(19) United States
(12) Patent Application Publication
(10) Pub. No.: US 2026/0293749 A1
(43) Pub. Date: Sep. 24, 2026

(54) STACKED MEMORY DIES WITH PROTECTIVE BARRIER

(71) Applicant: Sandisk Technologies, Inc., Milpitas, CA (US)

(72) Inventors: Yangming Liu, Shanghai (CN); Bo Yang, Milpitas, CA (US); Ning Ye, San Jose, CA (US)

(73) Assignee: Sandisk Technologies, Inc., Milpitas, CA (US)

(21) Appl. No.: 19/083,472

(22) Filed: Mar. 19, 2025

(51) Int. Cl. H01L 23/31; H01L 21/56; H01L 23/00; H01L 23/29; H01L 25/04; H10B 80/00

(52) U.S. Cl. CPC H10W 74/121; H10W 74/01; H10W 90/00; H10B 80/00; H10W 74/47; H10W 74/481; H10W 90/24; H10W 90/752; H10W 90/754

(57) ABSTRACT

An apparatus includes a plurality of memory dies arranged in a stack with lateral offsets to form steps along a stepped side of the stack. Bond pads are located on the steps. Molding compound overlies the stack. A protective barrier extends between the molding compound and the stepped side of the stack.

### BACKGROUND

The present disclosure relates to non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in a memory system typically contains many memory cells and various control lines. The memory structure may be three-dimensional (3D) and may include vertical NAND strings. Other memory structures may also be used.

A memory system may have control circuits to perform various operations (e.g., read, write and erase). Some or all control circuits may be located on a separate die (e.g., a memory structure may be located on a memory die and control circuits may be located on a control die that is electrically connected to the memory die). Memory dies (with or without control dies) may be arranged in a stack with electrical connections between memory dies. In some cases, a memory system may include a memory controller die and/or other dies that is/are connected to a stack of memory dies and packaged together. Electrically connecting and packaging dies in such a memory system in a reliable and cost-effective manner can be challenging.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 3 shows an example of a stack of memory dies with a stepped side.

FIG. 4 shows an example of a stack of memory dies with two stepped sides.

FIG. 5 shows a die stack including a stepped side with bond wires.

FIGS. 6A-B illustrate electrical connection between memory dies.

FIG. 7 illustrates an example of a protective barrier that protects a stepped side of a stack of memory dies.

FIG. 8 illustrates an example of protective barriers that protect stepped sides of a stack of memory dies.

FIGS. 9A-B show a perspective view of a stack of memory dies and a protective barrier.

FIGS. 10A-E illustrate a series of steps to protect a stepped side of a stack of memory cells.

FIG. 11 illustrates a method that includes placing a portion of protective material over a stepped side of a stack.

FIG. 12 illustrates a method that includes forming an encapsulant layer on a surface of a protective barrier and placing the protective barrier over a stepped side of a stack.

### DETAILED DESCRIPTION

A die stack may be formed of multiple dies, such as memory dies, which may be stacked with lateral offsets so that the stack includes a stepped side where bond pads of the dies are exposed. Bond pads of different dies of the stack may be connected by bond wires that extend over the stepped side. In an example, a protective barrier covers the stepped side of a stack and the components formed on and over the stepped side (e.g., components that form electrical connections, including bond wires and bond pads). For example, a silicon chip or die (e.g., planar portion of single crystal silicon) may be used as a protective barrier. An encapsulant layer may extend along the lower surface of the protective barrier so that, when the protective barrier is put in place, the encapsulant material fills the space between the protective barrier and the stepped side and encapsulates the bond wires (e.g., lies in contact with substantially all surfaces of bond wires with few, if any, voids). Subsequently, when a molding compound is added over the stack, the protective barrier provides protection from moisture and/or other contaminants that could otherwise cause problems including corrosion. The protective barrier and encapsulant may also reduce physical forces on bond wires that may cause failures.

Aspects of the present technology are directed to technical problems associated with connecting and packaging dies in a stack (e.g., a stack containing multiple memory dies) in a manner that is stable and reliable. Aspects of the present technology provide technical solutions including providing a protective barrier between a molding compound and a stepped side of a stack (e.g., where bond wires and bond pads are located). This can reduce or eliminate direct contact between molding compound and electrical conductors (e.g., bond pads and bond wires) and reduce exposure of electrical conductors to moisture and/or other contaminants that may migrate through molding compound.

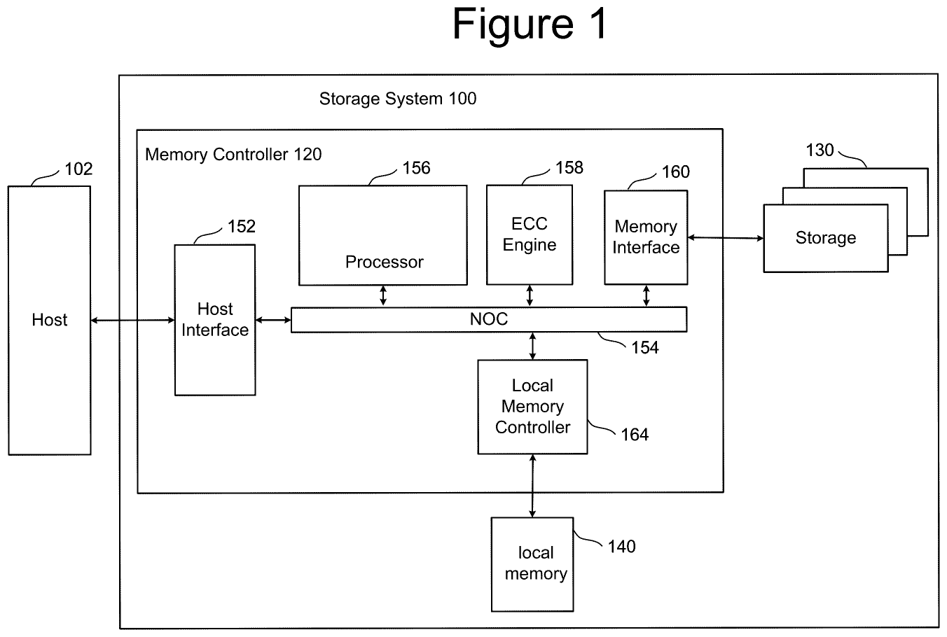

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface 160 provides a Toggle Mode interface. Other interfaces can also be used. In some example implementations, memory interface 160 (or another portion of memory controller 120) implements a scheduler and buffer for transmitting data to and receiving data from one or more memory die.

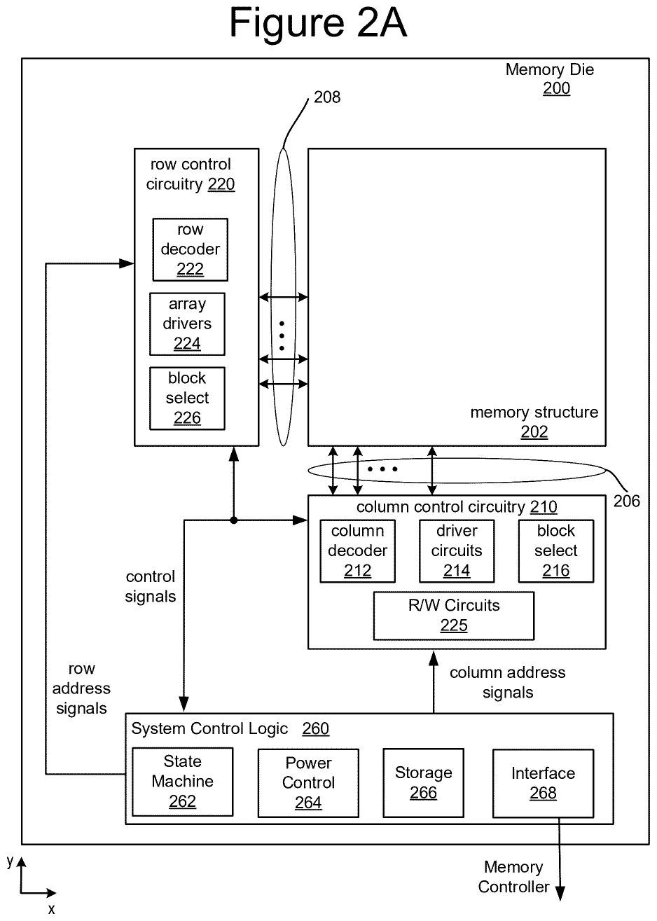

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 204.

In some embodiments, there is more than one control die 204 and more than one memory structure die 200 in an integrated memory assembly 207. In some embodiments, the integrated memory assembly 207 includes a stack of multiple control dies 204 and multiple memory structure dies 200.

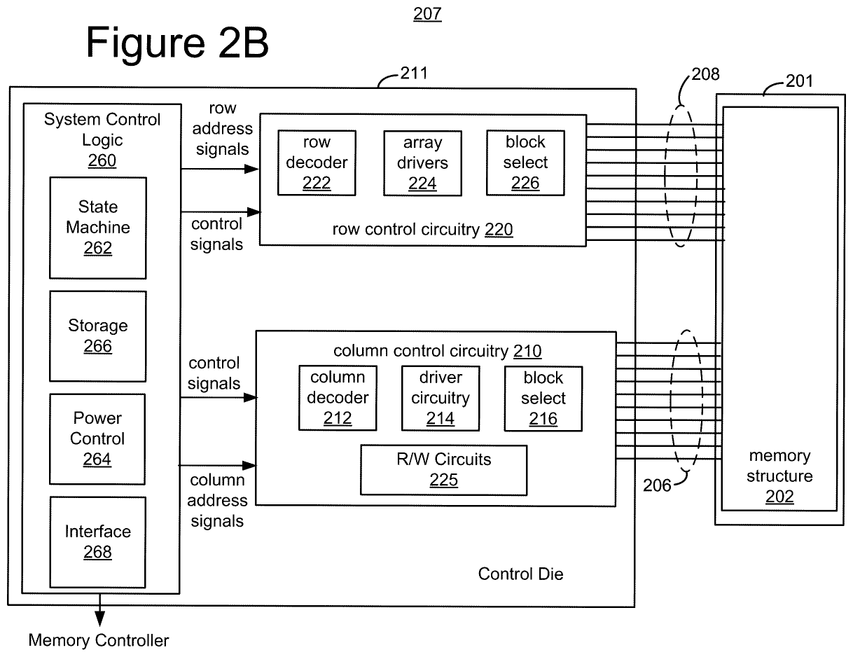

FIG. 3 depicts a side view of an embodiment of an integrated memory assembly 207 stacked on a substrate 271 (e.g., a stack comprising control die 204 and memory structure die). The integrated memory assembly 207 has three control dies 204 and three memory structure dies 200. In some embodiments, there are more than three memory structure dies 200 and more than three control dies 204. In FIG. 3 there are an equal number of memory structure dies 200 and control dies 204; however, in one embodiment, there are more memory structure dies 200 than control dies 204. For example, one control die 204 could control multiple memory structure dies 200.

Each control die 204 is affixed (e.g., bonded) to at least one of the memory structure die 200. Some of the bond pads 282/284 are depicted. There may be many more bond pads. A space between two die 200, 204 that are bonded together is filled with a solid layer 280, which may be formed from epoxy or other resin or polymer. This solid layer 280 protects the electrical connections between the die 200, 204, and further secures the die together. Various materials may be used as solid layer 280.

The integrated memory assembly 207 may for example be stacked with a stepped offset, leaving steps at each level so that the bond pads are exposed on each step and are accessible from above. Bond wires 270 connected to the bond pads connect the control die 204 to the substrate 271. A number of such bond wires may be formed across the width of each control die 204 (i.e., into the page of FIG. 3). While the stack of integrated memory assembly 207 shows a single stepped side (on the right in FIG. 3), more than one stepped side may be provided in some examples.

A memory die through silicon via (TSV) 276 may be used to route signals through a memory structure die 200. A control die through silicon via (TSV) 278 may be used to route signals through a control die 204. The TSVs 276, 278 may be formed before, during or after formation of the integrated circuits in dies 200, 204. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

As has been briefly discussed above, the control die 204 and the memory structure die 200 may be bonded together. Bond pads on each die 200, 204 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu. A memory die 200 bonded to a control die 204 may form an integrated memory assembly (also referred to as a CMOS bonded array or “CbA” module” including a memory die bonded to control die (e.g., logic or CMOS die).

When the area of bond pads is small, it may be difficult to bond the semiconductor die together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 200, 204. Where no such film is initially provided, a space between the die may be under filled with an epoxy or other resin or polymer. The under-fill material may be applied as a liquid which then hardens into a solid layer. This under-fill step protects the electrical connections between the dies 200, 204, and further secures the die together. Various materials may be used as under-fill material.

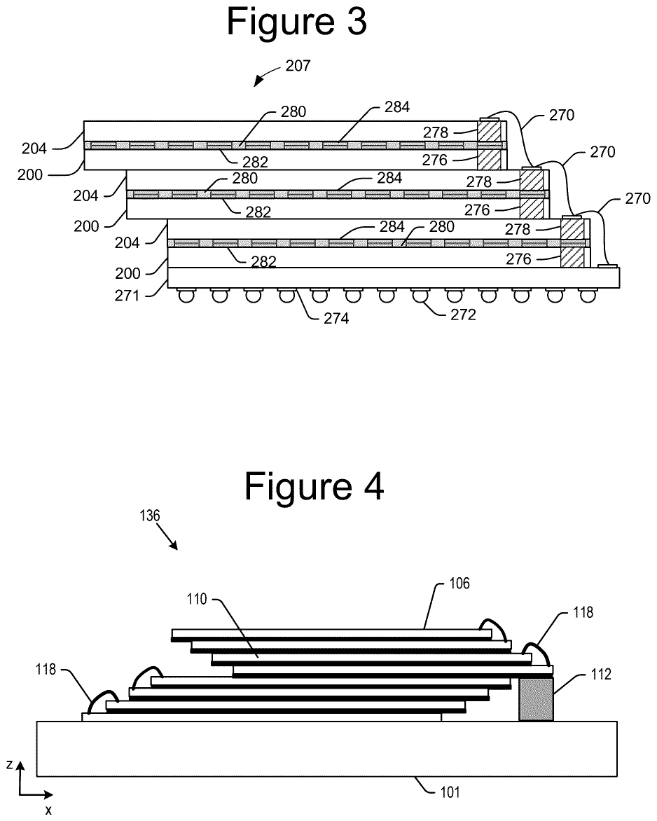

FIG. 4 shows another example of stacked semiconductor dies 106 in a semiconductor package 136. The semiconductor dies 106 may for example be memory dies such a NAND flash memory die, but other types of die 106 may be used. The memory dies may be in the form of integrated memory assemblies (e.g., in combination with control dies) or otherwise. The semiconductor dies 106 may be stacked on top of each other in an offset configuration (FIG. 3) or double offset configuration (FIG. 4) to form a die stack 110, which is shown extending in the z-direction (e.g., dies are stacked along the z-direction or up direction, where the x-y plane is considered horizontal so that dies 106 extend horizontally and are stacked vertically). The resulting stack may have one (FIG. 3) or two (FIG. 4) stepped sides where bond pads are exposed. The double offset configuration of FIG. 4 may comprise a spacer block 112 to support the upper dies 106 during wire bonding and encapsulation. The spacer block may be omitted in further embodiments.

In the example shown, the semiconductor package 136 includes eight semiconductor die 106. However, the die stack 110 may include more or less than eight semiconductor die in further embodiments, including for example 2, 4, 16 and 32 semiconductor die. The die 106 may be affixed to each other in the die stack 110 using a DAF (die attach film). As one example, the DAF may be 8988UV epoxy from Henkel Corp of California, USA.

Once the die stack 110 is mounted on the carrier 101, the respective dies 106 may be electrically connected to each other using bond wires 118. FIGS. 3, 4 and 5 show simplified edge and perspective views with a few bond wires shown for illustration purposes. There may be many more bond wires 118 than shown.

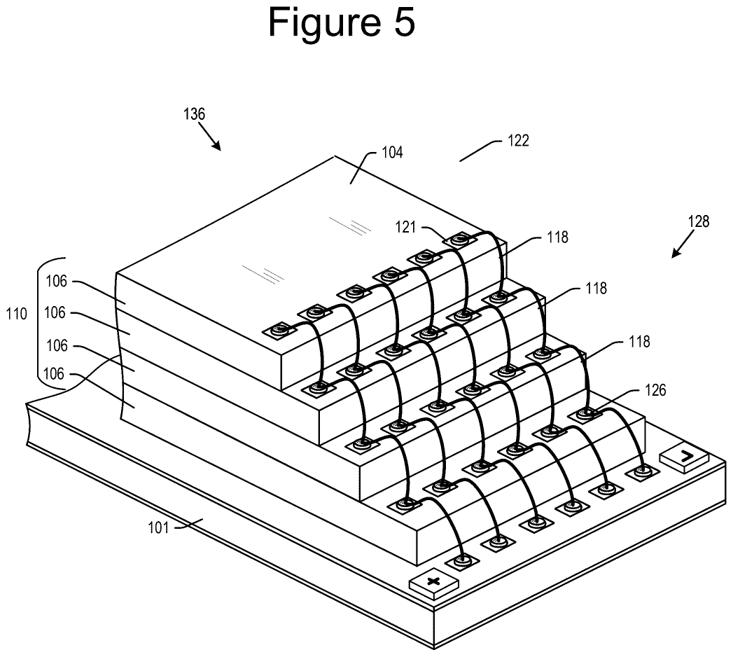

FIG. 5 illustrates a stepped side 128 of die stack 110 formed of semiconductor dies 106. Each semiconductor die 106 may include a row of die bond pads 121 exposed along a step formed on one or both edges of the dies 106. It is understood that each die 106 may include many more die bond pads 121 than is shown. Each die bond pad 121 in the row of a semiconductor die may be electrically connected to the corresponding die bond pad 121 in the row of the next adjacent semiconductor die using a bond wire 118 formed as described below.

In order to connect bond wires 118, in embodiments, a stud bump 126 may initially be deposited on each of the die bond pads 121. After the stud bumps 126 are deposited on the bond pads 121, stitch wire bonds may be formed on the stud bumps 126 on a die 106 (for example on the bottom die 106) up to the corresponding stud bumps 126 on the next higher die (for example the second die 106 from the bottom). This process may be repeated up the die stack 110 until bond wires 118 are formed between all corresponding die bond pads 121 in a column of die bond pads along stepped side 128 of die stack 110.

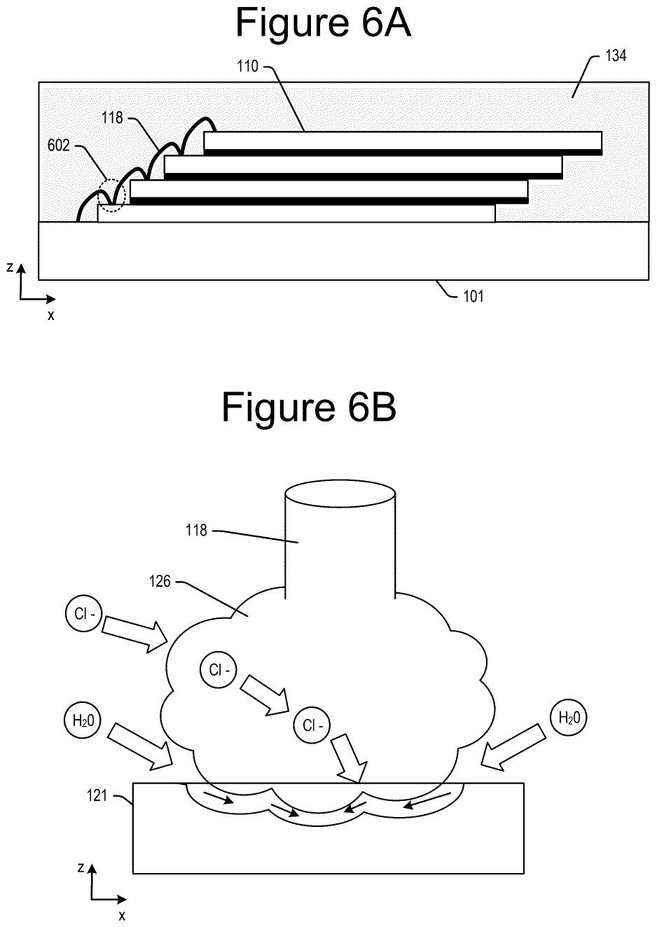

After the electrical connections are formed, the die stack 110 may be covered in a molding compound 134 that overlies die stack 110 as shown in FIG. 6A. The molding compound may be applied onto the surface of carrier 101, to surround and encapsulate die stack 110 and bond wires 118. Molding compound 134 may include for example solid epoxy resin, Phenol resin, fused silica, crystalline silica, carbon black and/or metal hydroxide. Such molding compounds are available for example from Sumitomo Corp. and Nitto-Denko Corp., both having headquarters in Japan. Other molding compounds from other manufacturers are contemplated. The molding compound may be applied according to various known processes, including by FFT (flow free thin) molding, transfer molding or injection molding techniques.

In some cases, bond wires (e.g., bond wires 118), die bond pads (e.g., die bond pads 121), stud bumps (e.g., stud bumps 126) and/or other conductive elements may fail or partially fail, which may cause problems including, but not limited to die failure, block failure, partial block failure, write fail, read fail, erase fail, high error rates and/or other problems. FIG. 6A illustrates a connection 602 between a wire bond and a die bond pad. Connection 602 is an example of a location where failure (e.g., connection failure) or partial failure (e.g., high resistance) may occur. Connection 602 is shown in more detail in FIG. 6B, which shows a bond pad 121 bonded to bond wire 118 by stud bump 126. FIG. 6B illustrates some examples of different failure modes that may be associated with such connections. The failure modes may include:
1. Moisture-related attack at ball bond side. For example, molding compound 134 may be moisture-absorptive and permeable to moisture so that moisture may migrate to connection 602 (e.g., from elsewhere in the package and/or from outside the package).
2. Inter-Metallic Compound (IMC) attacked by Chlorine ions (Cl-), which may be dissolved in moisture. For example, IMC may be formed by bonding of bond wire 118 to stud bump 126 and may be corroded or otherwise damaged by Cl- ions.
3. Hydrolysis of IMC (e.g., in the presence of moisture with bias applied), which may cause the IMC to become brittle (and more prone to breakage). Hydrolysis may also increase resistance so that even though the IMC may remain conductive, it may add significant resistance.
4. Cracking of Copper (Cu) to Copper Aluminum (CuAl) IMC (e.g., where bond wire 118 connects to IMC from stud bump 126) which may result from outgassing at or near the interface between these materials.

In addition to the problems illustrated in FIG. 6B, physical forces may cause some damage to connections such as connection 602. For example, external forces and forces due to particles or filler in the molding compound may produce significant force on connections, which may lead to failure and/or partial failure of connections (e.g., cracking and/or other physical damage to electrically conductive components, which may impact their capacity to conduct electrical current).

Aspects of the present technology are directed to technical problems associated with connections, such as connections 602, which may affect stacked dies that are packaged in a molding compound. Such problems may include those discussed above and/or other problems. Aspects of the present technology provide technical solutions that may include using one or more protective barrier to protect connections from moisture and its effects and/or to protect connections from mechanical forces that might otherwise cause physical breakage or damage.

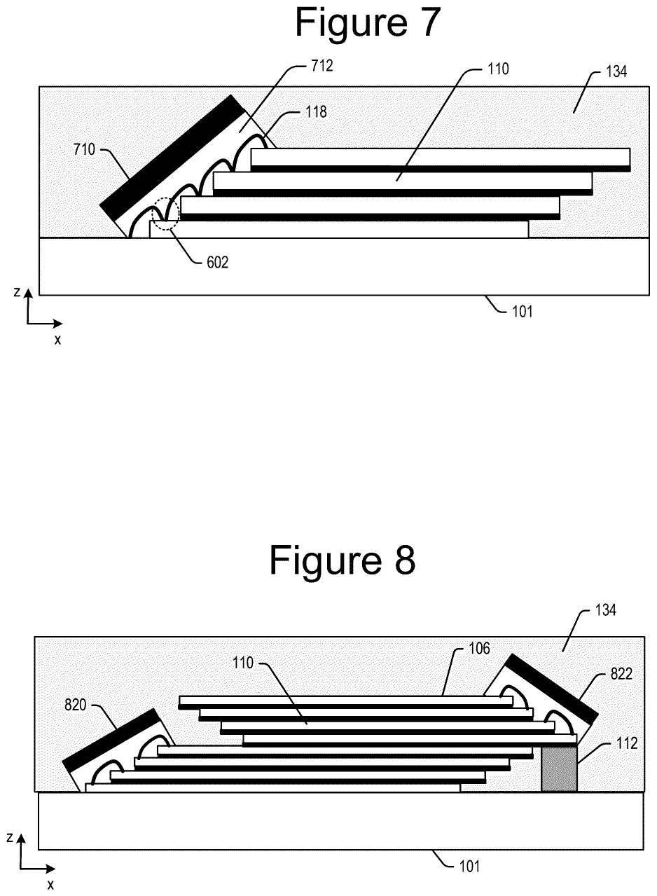

FIG. 7 illustrates an example of the present technology applied to a memory die stack 110 that includes memory dies connected by bond wires 118 as previously shown. FIG. 7 shows a protective barrier 710, which is arranged to significantly block moisture migration to connections such as connection 602. For example, while some opening may remain around edges of protective barrier 710 between protective barrier 710 and die stack 110, protective barrier 710 reduces the possible pathways for moisture and/or other contaminants (e.g., chlorine ions) to reach connections 602 and may reduce failures associated with moisture and/or other contaminants. Protective barrier 710 may be formed of a suitable material that provides a barrier to migration of water and/or other contaminants. In an example, protective barrier 710 is formed of the same material as memory dies of stack 110 (e.g., single crystal silicon) and may have a similar thickness. In other examples, protective barrier 710 may be formed of a metal such as aluminum, a metal alloy, ceramic, plastic or other material.

FIG. 7 also shows encapsulant 712, which encapsulates bond wires 118. Encapsulant 712 may be formed of a material that is different to molding compound 134 and that may provide certain advantages. For example, some or all of the failure modes discussed with respect to FIG. 6B may be significantly mitigated by filling the volume between protective barrier 710 and the stepped side of stack 110 with encapsulant 712 (e.g., in combination with protective barrier 710). For example, encapsulant 712 may have fewer and/or lower concentration of contaminants compared with molding compound 134. Encapsulant 712 may have smaller particles and/or fewer particles that could contribute to cracking.

In an example of the present technology, encapsulant 712 is formed as a DAF, which may be provided on a lower surface of protective barrier 710 prior to placement over the stepped side of stack 110. Encapsulant 712 may be formed of an epoxy (e.g., any epoxy resin or polyepoxide), which may be of a high purity (low level of contaminants and/or particles) and may have fluid properties (e.g., viscosity) that allow encapsulant 712 to conform to steps and to encapsulate bond wires without damaging bond wires. For example, encapsulant 712 may fill the volume between the steps and protective barrier 710 without significant voids by conforming to the stepped shape and flowing around bond wires. Protective barrier 710 (e.g., alone or in combination with encapsulant 712) may be considered a means for physically separating the molding compound from the stepped side of the stack, the bond pads and the bond wires.

While FIG. 7 shows a single protective barrier 710 covering a single stepped side of a stack that includes connections, the present technology may employ any number of protective barriers to protect stepped sides of stacks and corresponding connections.

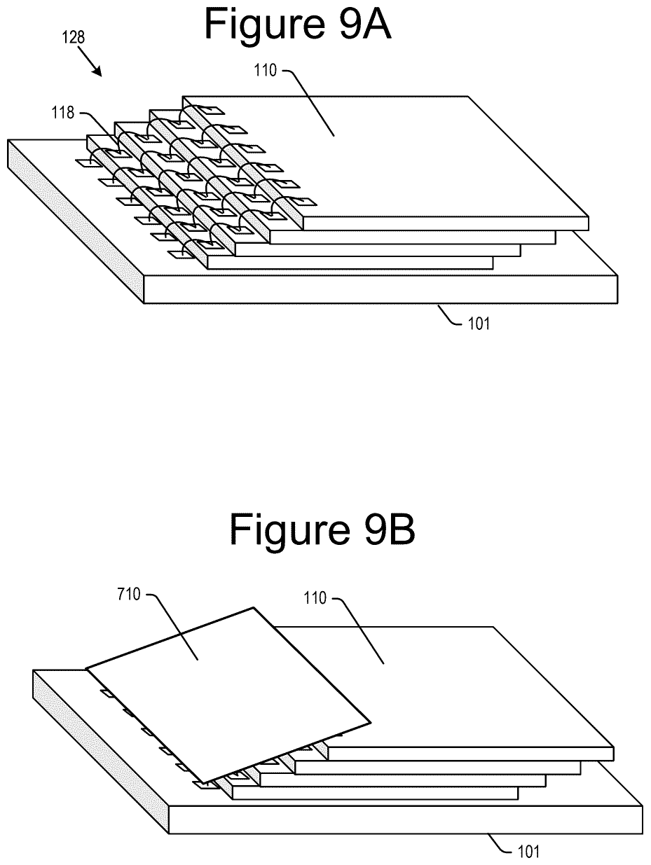

FIG. 8 shows an example of a stack 110 of semiconductor dies 106 that is similar to the stack shown in FIG. 4 (a stack formed with double offset to have two stepped sides, each with electrical connections that include bond pads and wire bonds). A first protective barrier 820 is located over one stepped side of stack 110 (on the left in FIG. 8) while a second protective barrier 822 is located over another stepped side of stack 110 (on the right in FIG. 8). The number and locations of protective barriers may differ according to the stack of dies and the location(s) of stepped side(s) in any such stacks. The present technology is not limited to the one and two barrier examples of FIGS. 7 and 8.

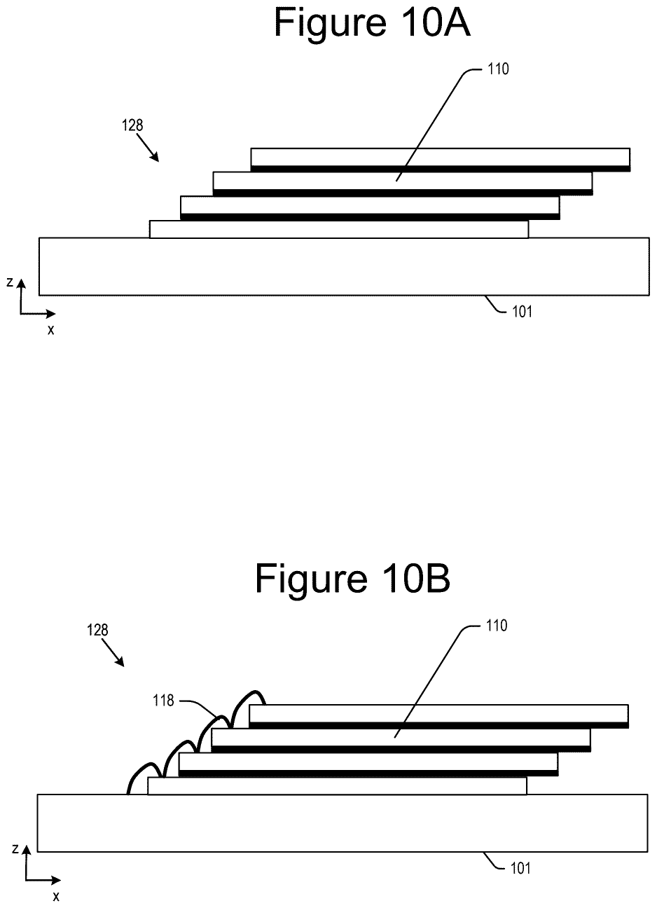

FIG. 9A shows a perspective view of stack 110 on carrier 101 including stepped side 128, with bond wires 118 connecting memory die of stack 110 as previously shown in FIG. 5. FIG. 9B shows stack 110 after protective barrier 710 is placed over stepped side 128 to cover connections between die (e.g., covering bond pads and wire bonds). While encapsulant is not visible in FIG. 9B, an encapsulant may substantially fill the volume between protective barrier 710 and stack 110.

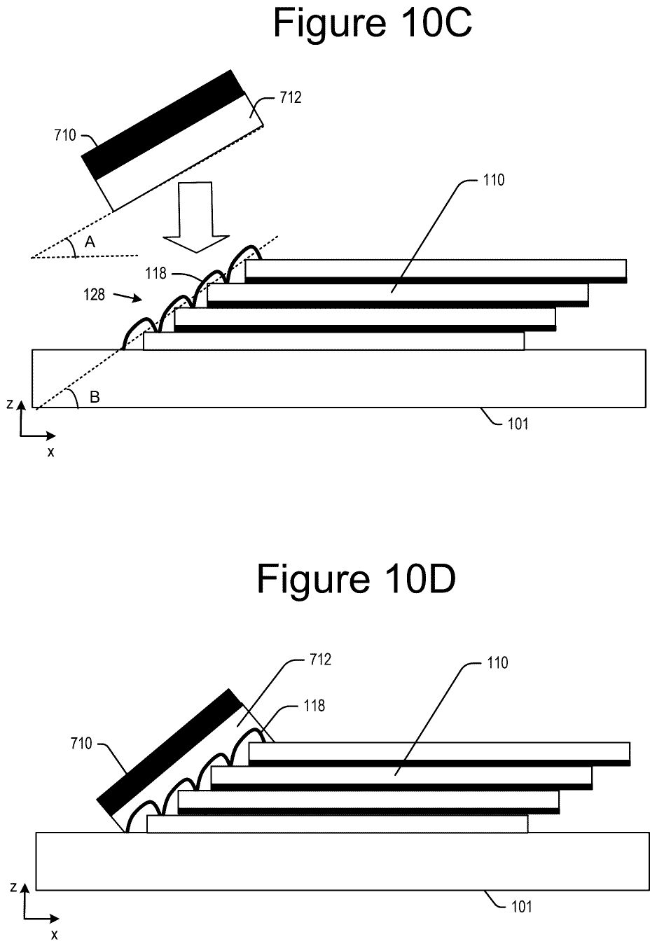

FIGS. 10A-E illustrate an example of a method that includes aspects of the present technology. FIG. 10A shows an example of a memory die stack 110 formed on a carrier 101 with lateral offsets such that bond pads of the memory dies are exposed along a stepped side 128 of stack 110 (e.g., as illustrated in FIGS. 5 and 9A). Memory dies in stack 110 may be physically attached by DAF or otherwise. Memory dies in stack 110 may be bonded with control dies in integrated memory assemblies or not.

FIG. 10B illustrates bonding exposed bond pads of the memory dies of stack 110 with bond wires 118 (e.g., bond pads 121 of stack 110 bonded by bond wires 118 as illustrated in FIG. 5).

FIG. 10C illustrates placing a protective barrier 710 (e.g., a portion of protective material such as silicon, metal or other solid material) over the stepped side 128 of stack 110, exposed bond pads and bond wires 118. FIG. 10C also shows an encapsulant layer 712 that is formed on the lower surface of protective barrier 710 prior to placing protective barrier 710 as shown. For example, encapsulant layer 712 may be spun-on, sprayed, deposited or otherwise formed on a surface to coat the surface. FIG. 10C also shows placing protective barrier 710 and encapsulant layer 712 with a tilt angle, A, with respect to the memory dies of stack 110. The tilt angle, A, is equal or substantially equal to the angle, B, of stepped side 128 such that the vertical distance between each step of the plurality of steps and protective barrier 710 is substantially equal. The angle of tilt, A, and angle B may be relatively small, for example, about 10 degrees or in a range between 5 and 15 degrees. Angles A and B may be substantially equal (e.g., different by less than 1 degree, 2 degrees, 3 degrees, or some other angular difference).

FIG. 10D illustrates the result of placing protective barrier 710 over stepped side 128 and bond wires 118, which causes encapsulant layer 712 to occupy the volume between the protective barrier 710 and stepped side 128 of stack 110 and to encapsulate bond wires 118. For example, encapsulant layer 712 may conform to stepped side 128 and flow around bond wires 118. In some cases, heat, pressure or other conditions may be applied to facilitate encapsulant layer 712 fully occupying this volume without significant voids and without significant damage to bond wires 118.

FIG. 10E illustrates covering stack 110 and protective barrier 710 with a molding compound 134. While molding compound 134 covers stack 110 and lies in contact with surfaces of memory dies of stack 110, protective barrier 710 (in combination with encapsulant layer 712) protects stepped side 128 and connections that are present on stepped side 128 (e.g., bond pads, bond wires and IMC or other connective components).

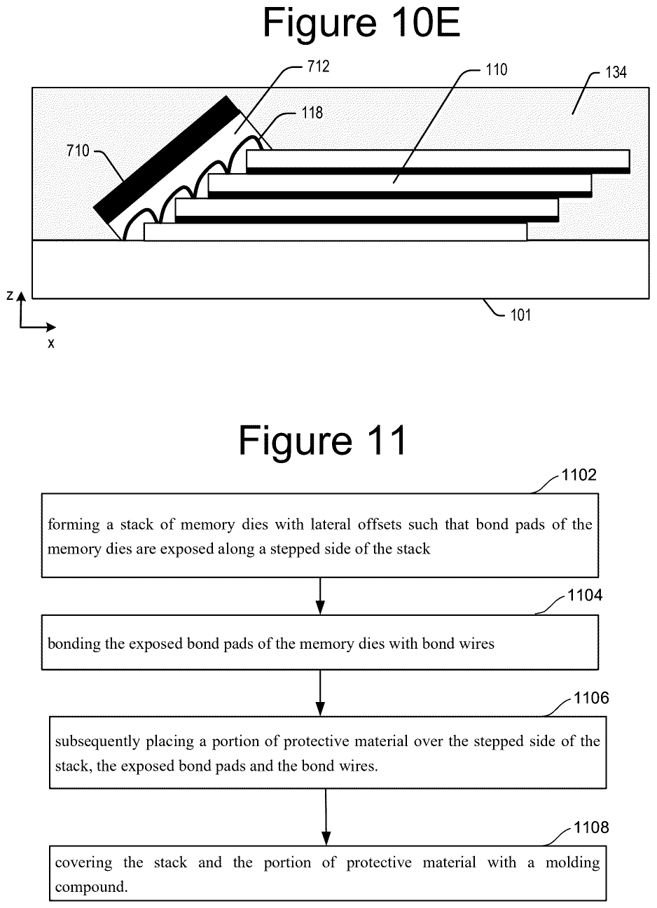

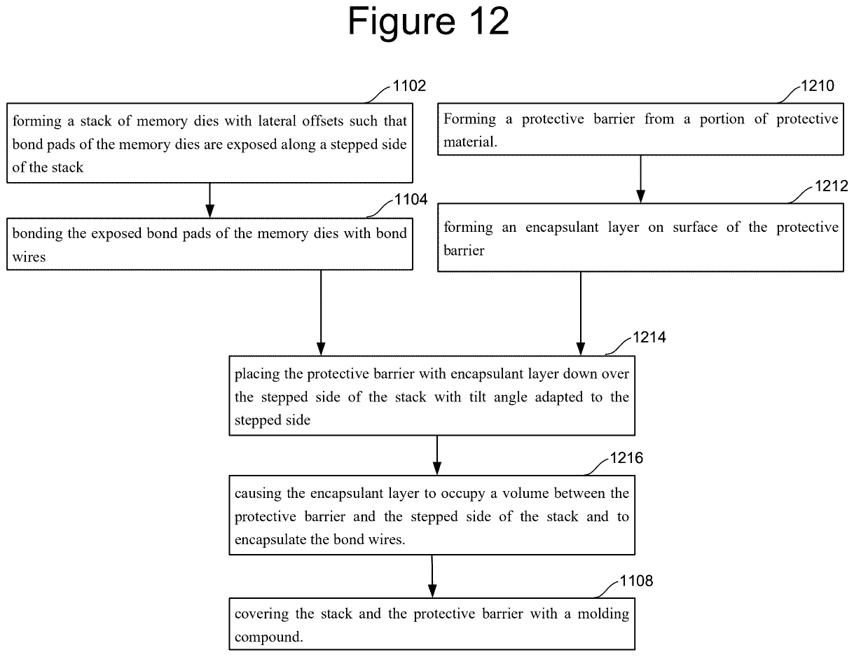

FIG. 11 illustrates a method that includes forming a stack of memory dies with lateral offsets such that bond pads of the memory dies are exposed along a stepped side of the stack 1102 (e.g., stack 110 with stepped side 128) and bonding the exposed bond pads of the memory dies with bond wires 1104 (e.g., bonding bond pads 121 of memory dies 106 with bond wires 118). The method further includes, subsequently placing a portion of protective material over the stepped side of the stack, the exposed bond pads and the bond wires 1106 (e.g., placing protective barrier 710 over stepped side 128, exposed bond pads 121 and bond wires 118) and covering the stack and the portion of protective material with a molding compound 1108 (e.g., covering stack 110 and protective barrier 710 with molding compound 134).
FIG. 12 illustrates a method in more detail than the example of FIG. 11 and includes forming a stack of memory dies with lateral offsets such that bond pads of the memory dies are exposed along a stepped side of the stack 1102 and bonding the exposed bond pads of the memory dies with bond wires 1104 as before. In addition, the method includes forming a protective barrier from a portion of protective material 1210 (e.g., a planar portion of material such as a silicon die) and forming an encapsulant layer on a surface of the protective barrier 1212 (e.g., adding a DAF). The method further includes, subsequently placing the protective barrier with the encapsulant layer down over the stepped side of the stack with tilt angle adapted to the stepped side 1214 (e.g., placing protective barrier 710 over stepped side 128 with encapsulant layer 712 facing down and a tilt angle A=angle B), causing the encapsulant layer to occupy a volume between the protective barrier and the stepped side of the stack and to encapsulate the bond wires 1216 and covering the stack and the protective barrier with a molding compound 1108.

According to an example, an apparatus includes a plurality of memory dies arranged in a stack with lateral offsets to form steps along a stepped side of the stack and bond pads located on the steps. Molding compound overlies the stack. A protective barrier extends between the molding compound and the stepped side of the stack.

In one or more embodiments, the apparatus further includes an encapsulant that occupies a volume between the protective barrier and the plurality of steps of the stepped side of the stack.

In one or more embodiments, the encapsulant is an epoxy.

In one or more embodiments, the protective barrier is a planar portion of a solid material.

In one or more embodiments, the protective barrier is formed of single crystal silicon.

In one or more embodiments, the apparatus further includes a plurality of bond wires extending between bond pads of the plurality of steps of the stepped side of the stack.

In one or more embodiments, the apparatus further includes an encapsulant that occupies a volume between the protective barrier and the plurality of steps, the encapsulant lying in contact with the plurality of steps and encapsulating the plurality of bond wires.

In one or more embodiments, the plurality of memory dies extend horizontally and the protective barrier is tilted from horizontal by a tilt angle.

In one or more embodiments, the tilt angle is such that vertical distance between each step of the plurality of steps and the protective barrier is substantially equal.

An example of a method includes forming a stack of memory dies with lateral offsets such that bond pads of the memory dies are exposed along a stepped side of the stack; bonding the bond pads of the memory dies with bond wires; and subsequently placing a portion of protective material over the stepped side of the stack, the bond pads and the bond wires.

In one or more embodiments, the method further includes placing the portion of protective material with a tilt angle with respect to the memory dies, the tilt angle is such that vertical distance between each step of a plurality of steps of the stepped side and the portion of protective material is substantially equal.

In one or more embodiments, the tilt angle is between 5 and 15 degrees.

In one or more embodiments, the method further includes forming an encapsulant layer on a lower surface of the portion of protective material prior to placing the portion of protective material.

In one or more embodiments, the method further includes causing the encapsulant layer to occupy a volume between the portion of protective material and the stepped side of the stack and to encapsulate the bond wires.

In one or more embodiments, the method further includes subsequently, covering the stack and the portion of protective material with a molding compound.

In one or more embodiments, the encapsulant layer is formed of an epoxy.

In one or more embodiments, the portion of protective material is a planar portion of single crystal silicon.

In one or more embodiments, each memory die of the stack of memory dies is bonded with a corresponding control die to form an integrated memory assembly.

An example of a storage system includes a plurality of memory dies that are stacked along a first direction with offsets along a second direction to form a stack with steps along a stepped side of the stack; bond wires connecting bond pads that are located on the steps; a molding compound that overlies the stack; and means for physically separating the molding compound from the stepped side of the stack, the bond pads and the bond wires.

In one or more embodiments, each memory die of the plurality of memory dies is bonded with a control die to form an integrated memory assembly.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element (other than possibly an adhesive or melted metal used to connect, affix, mount or couple the first and second elements). Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a plurality of memory dies arranged in a stack with lateral offsets to form a plurality of steps along a stepped side of the stack;
a plurality of bond pads located on the plurality of steps of the stepped side of the stack;
a molding compound that overlies the stack; and
a protective barrier that extends between the molding compound and the plurality of steps of the stepped side of the stack.

2. The apparatus of claim 1, further comprising an encapsulant that occupies a volume between the protective barrier and the plurality of steps of the stepped side of the stack.

3. The apparatus of claim 2, wherein the encapsulant is an epoxy.

4. The apparatus of claim 1, wherein the protective barrier is a planar portion of a solid material.

5. The apparatus of claim 4, wherein the protective barrier is formed of single crystal silicon.

6. The apparatus of claim 1, further comprising a plurality of bond wires extending between the bond pads of the plurality of steps of the stepped side of the stack.

7. The apparatus of claim 6, further comprising an encapsulant that occupies a volume between the protective barrier and the plurality of steps, the encapsulant lying in contact with the plurality of steps and encapsulating the plurality of bond wires.

8. The apparatus of claim 1, wherein the plurality of memory dies extend horizontally and the protective barrier is tilted from horizontal by a tilt angle.

9. The apparatus of claim 8, wherein the tilt angle is such that a vertical distance between each step of the plurality of steps and the protective barrier is substantially equal.

10. A method comprising:
forming a stack of memory dies with lateral offsets such that bond pads of the memory dies are exposed along a stepped side of the stack;
electrically connecting the bond pads of the memory dies with bond wires; and
subsequently placing a portion of protective material over the stepped side of the stack, the bond pads and the bond wires.

11. The method of claim 10, further comprising placing the portion of protective material with a tilt angle with respect to the memory dies, the tilt angle is such that a vertical distance between each step of a plurality of steps of the stepped side and the portion of protective material is substantially equal.

12. The method of claim 11, wherein the tilt angle is between 5 and 15 degrees.

13. The method of claim 10, further comprising forming an encapsulant layer on a lower surface of the portion of protective material prior to placing the portion of protective material.

14. The method of claim 13, further comprising causing the encapsulant layer to occupy a volume between the portion of protective material and the stepped side of the stack and to encapsulate the bond wires.

15. The method of claim 14, further comprising:
subsequently, covering the stack and the portion of protective material with a molding compound.

16. The method of claim 13, wherein the encapsulant layer is formed of an epoxy.

17. The method of claim 10, wherein the portion of protective material is a planar portion of single crystal silicon.

18. The method of claim 10, wherein each memory die of the stack of memory dies is electrically connected to a control die to form an integrated memory assembly.

19. A storage system, comprising:
a plurality of memory dies that are stacked along a first direction with offsets along a second direction to form a stack with steps along a stepped side of the stack;
bond wires connecting bond pads that are located on the steps;
a molding compound that overlies the stack; and
means for physically separating the molding compound from the stepped side of the stack, the bond pads and the bond wires.

20. The storage system of claim 19, wherein each memory die of the plurality of memory dies is electrically connected with a control die to form an integrated memory assembly.
